(19) United States
(12) Patent Application Publication
(10) Pub. No.: US 2022/0344485 A1
(43) Pub. Date: Oct. 27, 2022

(54) Gallium Nitride Device, Switching Power Transistor, Drive Circuit, and Gallium Nitride Device Production Method

(71) Applicant: Huawei Technologies Co., Ltd., Shenzhen (CN)

(72) Inventors: Qilong Bao, Dongguan (CN); Qimeng Jiang, Shenzhen (CN); Gaofei Tang, Dongguan (CN); Hanxing Wang, Dongguan (CN); Boning Huang, Dongguan (CN); Zhaozheng Hou, Dongguan (CN)

(21) Appl. No.: 17/727,221

(22) Filed: Apr. 22, 2022

(30) Foreign Application Priority Data
Apr. 22, 2021 (CN) 202110436275.X

(51) Int. Cl. H01L 29/45; H03K 17/041; H01L 29/778; H01L 29/66; H01L 29/40; H01L 29/417

(52) U.S. Cl. CPC H01L 29/452; H03K 17/04106; H01L 29/7786; H01L 29/66462; H01L 29/401; H01L 29/41775

(57) ABSTRACT

A gallium nitride (GaN) device, where a drain of the GaN device includes a p-type (P-GaN) layer and a drain metal. The drain metal includes a plurality of first structural intervals and a plurality of second structural intervals. The plurality of first structural intervals and the plurality of second structural intervals are alternately distributed in the gate width direction. In this way, the drain metal implements local injection of holes for the device in the first structural intervals, and forms ohmic contact in the second structural intervals, implementing current conduction from a drain to a source of the device.

### CROSS-REFERENCE TO RELATED APPLICATIONS

This claims priority to Chinese Patent Application No. 202110436275.X filed on Apr. 22, 2021, which is hereby incorporated by reference in its entirety.

### TECHNICAL FIELD

This disclosure relates to the field of semiconductor technologies, and in particular, to a gallium nitride (GaN) device, a switching power transistor, a drive circuit, and a GaN device production method.

### BACKGROUND

As requirements for low energy consumption, high efficiency, and high power density of a semiconductor device currently become increasingly obvious in the industry, a GaN device (for example, a switching device such as a field effect transistor) produced based on GaN has attracted increasing attention.

The GaN device mainly includes a device that is based on an aluminum GaN (AlGaN)/GaN lateral heterostructure. Because the AlGaN/GaN heterostructure has a high two-dimensional electronic gas (2DEG) channel at an interface of the AlGaN/GaN heterostructure, a 2DEG channel with high electron mobility can be naturally formed at the interface of the AlGaN/GaN heterostructure. Therefore, compared with a semiconductor silicon device, the GaN device has lower energy consumption, higher efficiency, and higher power density.

However, a GaN device produced based on a current production process usually has some deficiencies. These deficiencies may lead to a “current collapse” effect in the GaN device. The “current collapse” effect herein means an increase in an on-resistance of the GaN device, which reduces a switching speed of the GaN device, increases a driving loss, and reduces reliability of the device.

### SUMMARY

Embodiments of this disclosure provide a GaN device, a switching power transistor, a drive circuit, and a GaN device production method, to avoid an increase in an intrinsic on-resistance of the device while ensuring efficiency of hole injection at p-type doped GaN (P-GaN), thereby increasing a switching speed of the device, reducing a driving loss of the device, and improving reliability of the device.

According to a first aspect, an embodiment of this disclosure provides a GaN device. The GaN device includes a substrate, a buffer layer formed over the substrate, a GaN layer formed over the buffer layer, an AlGaN layer formed over the GaN layer, and a source, a drain, and a gate that are formed on the AlGaN layer. The drain includes a P-GaN layer and a drain metal. The P-GaN layer is formed on the AlGaN layer, and is of a strip structure in a gate width direction of the device. The drain metal includes a plurality of first structural intervals and a plurality of second structural intervals. The plurality of first structural intervals and the plurality of second structural intervals are alternately distributed in the gate width direction. In the first structural intervals, the drain metal is in contact with the P-GaN layer, and in the second structural intervals, the drain metal is in contact with the P-GaN layer and forms ohmic contact with the AlGaN layer.

According to the foregoing technical solution, the drain metal is in contact with the P-GaN layer in the first structural intervals, implementing local injection of holes, and the drain metal forms ohmic contact with the AlGaN layer in the second structural intervals, implementing current conduction from the drain to the source of the device. Therefore, while efficiency of hole injection at P-GaN is ensured, the device does not have an excessively large intrinsic on-resistance, thereby increasing a switching speed of the device, reducing a driving loss of the device, and improving reliability of the device. In addition, when the GaN device is produced, the P-GaN layer does not need to be etched into a discontinuous structure, thereby avoiding an impact of etching precision on performance of the device, and allowing a simpler process.

With reference to the first aspect, in a first possible implementation of the first aspect, in the first structural intervals, the drain metal is formed on the P-GaN layer, and a width of the drain metal in a direction perpendicular to the gate width direction is less than or equal to a width of the P-GaN layer. In this way, the P-GaN layer can isolate the drain metal from the AlGaN layer, so that the drain metal is not in contact with the AlGaN layer. Therefore, electrons of the drain metal are not injected into the AlGaN layer that is under the drain metal, and in the device, local holes are formed under the drain metal, implementing local injection of holes for the device. The local holes can compensate for a negative electron trap, so that electrons captured by the electron trap are released, avoiding a “current collapse” effect.

With reference to the first aspect, in a second possible implementation of the first aspect, in the first structural intervals, the drain metal is formed on the P-GaN layer, a width of the drain metal in a direction perpendicular to the gate width direction is greater than a width of the P-GaN layer, the drain metal includes extension portions located on two sides of the P-GaN layer, and the extension portions are isolated from the AlGaN layer by passivation layers. In this way, although the width of the drain metal is greater than the width of the P-GaN layer, the drain metal is not in contact with the AlGaN layer due to the passivation layers. Therefore, electrons of the drain metal are not injected into the AlGaN layer that is under the drain metal, and in the device, local holes are formed under the drain metal, implementing local injection of holes for the device. The local holes can compensate for a negative electron trap, so that electrons captured by the electron trap are released, avoiding a “current collapse” effect.

With reference to the first aspect and the first and second possible implementations of the first aspect, in a third possible implementation of the first aspect, in the second structural intervals, the drain metal is formed on the P-GaN layer and the AlGaN layer, the width of the drain metal is greater than the width of the P-GaN layer, the drain metal includes the extension portions located on the two sides of the P-GaN layer, and the extension portions form ohmic contact with the AlGaN layer. In this way, because the width of the drain metal is greater than the width of the P-GaN layer, the drain metal located outside a width range of the P-GaN layer can form ohmic contact with the AlGaN layer, implementing current conduction from the drain to the source of the device.

With reference to the first aspect and the first to third possible implementations of the first aspect, in a fourth possible implementation of the first aspect, the P-GaN layer has a same width in all positions in the gate width direction. In this way, when the P-GaN layer is etched, it is not necessary to control etching precision in each position of the P-GaN layer for different widths, thereby reducing a difficulty of a process.

With reference to the third possible implementation of the first aspect, in a fifth possible implementation of the first aspect, the drain metal has a same width in all positions in the gate width direction. In this way, when the drain metal is etched, it is not necessary to control etching precision in each position of the P-GaN layer for different widths, thereby reducing a difficulty of a process.

With reference to the first aspect and the first to fifth possible implementations of the first aspect, in a sixth possible implementation of the first aspect, the plurality of first structural intervals and the plurality of second structural intervals are an integrated structure. In this way, when the drain metal is etched, it is not necessary to control etching spacing between the first structural interval and the second structural interval, to reduce the difficulty of the process.

With reference to the first aspect and the first to fifth possible implementations of the first aspect, in a seventh possible implementation of the first aspect, the plurality of first structural intervals and the plurality of second structural intervals are alternately distributed in the gate width direction, and there is specific spacing between a first structural interval and a second structural interval that are adjacent.

According to a second aspect, an embodiment of this disclosure provides a GaN device production method. The method is used for producing the GaN device according to the first embodiment and the implementations of the first embodiment in this disclosure. The method includes epitaxially growing a buffer layer, a GaN layer, and an AlGaN layer sequentially from bottom to top on a substrate, etching a P-GaN layer on the AlGaN layer, where the P-GaN layer is of a continuous strip structure in a gate width direction, and producing a drain metal on the P-GaN layer and the AlGaN layer that is located on two sides of the P-GaN layer, so that the drain metal has a plurality of first structural intervals and a plurality of second structural intervals that are alternately distributed in the gate width direction.

According to the foregoing technical solution, the drain metal is in contact with the P-GaN layer in the first structural intervals, implementing local injection of holes, and the drain metal forms ohmic contact with the AlGaN layer in the second structural intervals, implementing current conduction from the drain to the source of the device. Therefore, while efficiency of hole injection at P-GaN is ensured, the device does not have an excessively large intrinsic on-resistance, thereby increasing a switching speed of the device, reducing a driving loss of the device, and improving reliability of the device. In addition, when the GaN device is produced, the P-GaN layer does not need to be etched into a discontinuous structure, thereby avoiding an impact of etching precision on performance of the device, and allowing a simpler process.

With reference to the second aspect, in a first possible implementation of the first aspect, the first structural intervals are obtained by using the following method: etching the drain metal on the P-GaN layer, where a width of the drain metal is less than or equal to a width of the P-GaN layer, to form the first structural intervals. In this way, the P-GaN layer can isolate the drain metal from the AlGaN layer, so that the drain metal is not in contact with the AlGaN layer. Therefore, electrons of the drain metal are not injected into the AlGaN layer that is under the drain metal, and in the device, local holes are formed under the drain metal, implementing local injection of holes for the device. The local holes can compensate for a negative electron trap, so that electrons captured by the electron trap are released, avoiding a “current collapse” effect.

With reference to the second aspect, in a second possible implementation of the first aspect, the second structural intervals are obtained by using the following method: etching the drain metal on the P-GaN layer and the AlGaN layer that is located on the two sides of the P-GaN layer, where the drain metal includes extension portions located on the two sides of the P-GaN layer, and the extension portions form ohmic contact with the AlGaN layer, to form the second structural intervals. In this way, because a width of the drain metal is greater than a width of the P-GaN layer, the drain metal located outside a width range of the P-GaN layer can form ohmic contact with the AlGaN layer, implementing current conduction from the drain to the source of the device.

With reference to the second aspect, in a third possible implementation of the first aspect, the first structural intervals and the second structural intervals are obtained by using the following method: performing etching removal, at intervals in the gate width direction, on passivation layers that are in areas on the two sides of the P-GaN layer, and etching the drain metal on the P-GaN layer and the AlGaN layer that is located on the two sides of the P-GaN layer, where the drain metal includes extension portions located on the two sides of the P-GaN layer, in areas in which the passivation layers are not removed by etching, the extension portions are isolated from the AlGaN layer by the passivation layers, to form the first structural intervals, and in areas in which the passivation layers are removed by etching, the extension portions are in contact with the AlGaN layer, to form the second structural intervals. In this way, in the first structural intervals, the P-GaN layer can isolate the drain metal from the AlGaN layer, so that the drain metal is not in contact with the AlGaN layer. Therefore, electrons of the drain metal are not injected into the AlGaN layer that is under the drain metal, and in the device, local holes are formed under the drain metal, implementing local injection of holes for the device. The local holes can compensate for a negative electron trap, so that electrons captured by the electron trap are released, avoiding a “current collapse” effect. In the second structural intervals, because a width of the drain metal is greater than a width of the P-GaN layer, the drain metal located outside a width range of the P-GaN layer can form ohmic contact with the AlGaN layer, implementing current conduction from the drain to the source of the device.

According to a third aspect, an embodiment of this disclosure provides a drive circuit. The drive circuit includes a gate driver and the GaN device according to the first aspect and the implementations of the first aspect in the embodiments of this disclosure. A gate of the GaN device is coupled to a signal output terminal of the gate driver, and a source and a drain of the GaN device are coupled into a load circuit. The gate driver is configured to output a first potential to turn on the GaN device, and output a second potential to turn off the GaN device, where the first potential is higher than a turn-on potential of the GaN device, and the second potential is lower than the turn-on potential of the GaN device. In this way, the GaN device may be used as a switching device in the load circuit, and is controlled to be on and off by the gate driver. Because the GaN device overcomes a “current collapse” effect and has a small intrinsic on-resistance and a small device loss, overall operating efficiency of the load circuit can be improved, a total amount of heat generated by the load circuit can be reduced, and operating stability of the load circuit can be improved.

### DESCRIPTION OF DRAWINGS

FIG. 1 is a schematic diagram of a section of a common GaN device;

FIG. 2 is a schematic diagram of a section of a GaN device used to suppress a “current collapse” effect;

FIG. 3 is a three-dimensional view of a GaN device used to suppress a “current collapse” effect;

FIG. 4 is a three-dimensional view of a GaN device according to Embodiment 1 of this disclosure;

FIG. 5 is a view of a partial section of a first structural interval in a direction A according to Embodiment 1 of this disclosure;

FIG. 6 is a view of a partial section of a second structural interval in a direction A according to Embodiment 1 of this disclosure;

FIG. 7A, FIG. 7B, and FIG. 7C are a flowchart of a GaN device production method according to Embodiment 2 of this disclosure;

FIG. 8 is a three-dimensional view of a GaN device according to Embodiment 3 of this disclosure;

FIG. 9 is a view of a partial section of a first structural interval according to Embodiment 3 of this disclosure;

FIG. 10 is a view of a partial section of a second structural interval according to Embodiment 3 of this disclosure;

FIG. 11A, FIG. 11B, and FIG. 11C are a flowchart of a GaN device production method according to Embodiment 4 of this disclosure; and

FIG. 12 is a three-dimensional view of a structure of a GaN device according to Embodiment 5 of this disclosure.

Illustration: 100: substrate, 200: buffer layer, 300: GaN layer, 400: AlGaN layer, 410: passivation layer, 500: P-GaN layer, 610: first structural interval, 620: second structural interval, and 621: extension portion.

### DESCRIPTION OF EMBODIMENTS

GaN is a compound of nitrogen and gallium, and is a direct band gap semiconductor of group III (boron group element) and group V (nitrogen group element). GaN has a wide band gap of 3.4 electron volts (eV), while silicon, a currently most commonly used semiconductor material, has a band gap of 1.12 eV. Therefore, GaN has better performance than a silicon component in high-power and high-speed components.

As requirements for low energy consumption, high efficiency, and high power density of a semiconductor device currently become increasingly obvious in the industry, a GaN device (for example, a switching device such as a field effect transistor and a switching power transistor) produced based on GaN has attracted increasing attention. The GaN device mainly includes a device that is based on an AlGaN/GaN lateral heterostructure. Because the AlGaN/GaN heterostructure has a high 2DEG channel at an interface of the AlGaN/GaN heterostructure, a 2DEG channel with high electron mobility can be naturally formed at the interface of the AlGaN/GaN heterostructure. Therefore, compared with a semiconductor silicon device, the GaN device has lower energy consumption, higher efficiency, and higher power density. In addition, GaN is a wide band gap semiconductor, and has a high operating temperature, which usually can reach at least 500 degrees Celsius (° C.). Therefore, the GaN device can operate under high temperature conditions. In addition, GaN further has a high breakdown electric field. Therefore, the GaN device has a high gate-drain breakdown voltage and can operate under high voltage conditions.

Although the GaN device meets the industry's requirements for low energy consumption, high efficiency, and high power density of semiconductor devices, a GaN device produced based on a current production process usually has some deficiencies. These deficiencies may lead to a “current collapse” effect in the GaN device. The “current collapse” effect herein means an increase in an on-resistance of the GaN device, which affects operating stability of a system.

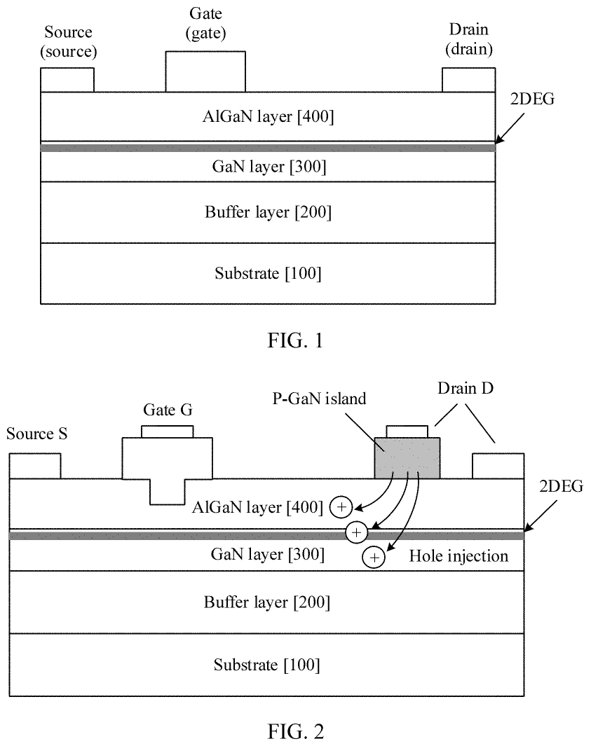

FIG. 1 is a schematic diagram of a section of a common GaN device. The following further describes causes of the deficiencies in the GaN device with reference to FIG. 1. As shown in FIG. 1, because the GaN device lacks a self-supporting substrate, the GaN device usually needs to be produced by using an epitaxially growing method. Further, first, a buffer layer 200 may be epitaxially grown over a substrate 100 (which is usually silicon Si), then, a GaN layer 300 may be epitaxially grown over the buffer layer 200, then, an AlGaN layer 400 may be epitaxially grown over the GaN layer 300, to obtain an AlGaN/GaN lateral heterostructure, and finally, a source (S), a drain (D), and a gate (G) may be produced on the AlGaN layer 400. In this way, the GaN device is produced.

However, because the substrate and the GaN are of different materials and have different lattice constants and different coefficients of thermal expansion, an epitaxial layer has a crack due to problems such as a lattice mismatch and a thermal expansion mismatch between the substrate and the GaN, causing a large quantity of deficiencies in the GaN epitaxial material. These deficiencies capture electrons, resulting in a decrease in a concentration of carriers that are in an operating state in the device, and consequently a “current collapse” effect in the device.

FIG. 2 is a schematic diagram of a section of a GaN device used to suppress a “current collapse” effect. As shown in FIG. 2, currently, a method for suppressing the “current collapse” effect is to introduce a P-GaN island structure to a drain D of a GaN device. The P-GaN island structure can implement hole injection in a local area. A hole of positive charges can compensate for a negative electron trap, so that electrons captured by the electron trap are released.

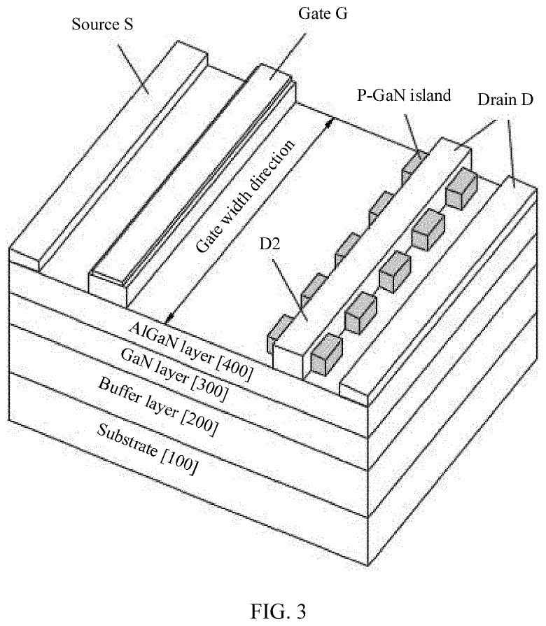

FIG. 3 is a three-dimensional view of a GaN device used to suppress a “current collapse” effect. As shown in FIG. 3, in a gate width direction, the P-GaN island structure may include a drain metal D2 and a plurality of P-GaN islands distributed as islands. The plurality of P-GaN islands are distributed at intervals in the gate width direction, and the drain metal D2 is continuously distributed in the gate width direction. In areas in which the P-GaN islands are distributed, the drain metal D2 grows on the P-GaN islands, to implement local hole injection. In areas in which no P-GaN island is distributed, the drain metal D2 grows on an AlGaN layer. In this way, when the plurality of P-GaN islands are distributed at intervals, a substantial increase in an intrinsic on-resistance of the device can be avoided without causing a substantial loss of chip performance.

However, in actual production, the discontinuous structure of the P-GaN islands needs to be obtained through etching, and design of a spacing distance and etching precision both affect a spacing distance between produced P-GaN islands. Therefore, the spacing distance between the P-GaN islands is quite difficult to control. An excessively large spacing distance results in a decrease in efficiency of hole injection in the P-GaN island structure and further a decrease in a compensation effect of the electron trap. An excessively small spacing distance results in an increase in the intrinsic on-resistance of the device, a decrease in performance of the device, and an increase in use costs of the device.

### Embodiment 1

Embodiment 1 of this disclosure provides a GaN device, to reduce a risk of an increase in an intrinsic on-resistance of the device while ensuring efficiency of hole injection at P-GaN.

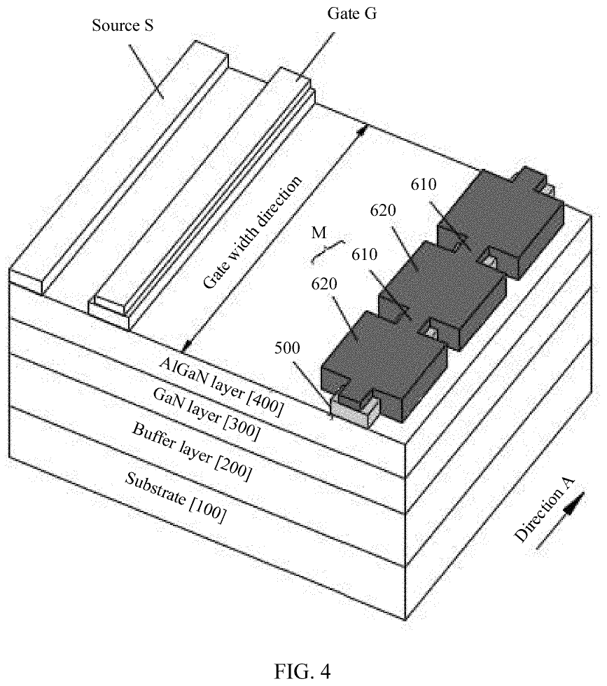

FIG. 4 is a three-dimensional view of a GaN device according to Embodiment 1 of this disclosure. As shown in FIG. 4, the GaN device includes a substrate 100, a buffer layer 200 formed over the substrate 100, a GaN layer 300 formed over the buffer layer 200, an AlGaN layer 400 formed over the GaN layer 300, and a source (S), a drain (D), and a gate (G) formed on the AlGaN layer 400. The drain (D) includes a P-GaN layer 500 formed on the AlGaN layer 400, and a drain metal M disposed on the P-GaN layer 500 and on the AlGaN layer 400 that is on two sides of the P-GaN layer 500. The drain metal M may be an ohmic metal.

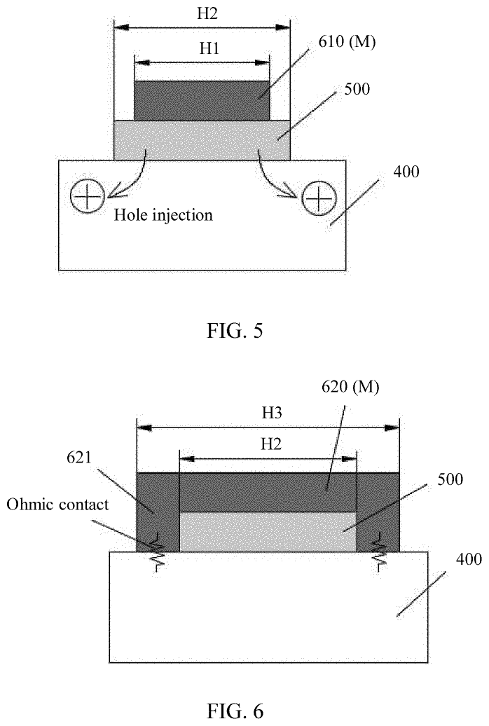

In specific implementation, the P-GaN layer 500 is of a strip structure. The P-GaN layer 500 has a same width in all positions in a gate width direction. The drain metal M may include a plurality of first structural intervals 610 and a plurality of second structural intervals 620 in the gate width direction. The plurality of first structural intervals 610 and the plurality of second structural intervals 620 are alternately distributed in the gate width direction. The plurality of first structural intervals 610 and the plurality of second structural intervals 620 are an integrated structure in the gate width direction. FIG. 5 is a view of a partial section of a first structural interval 610 in a direction A according to Embodiment 1 of this disclosure. As shown in FIG. 5, in the first structural interval 610, the drain metal M is formed on the P-GaN layer 500. A width H1 of the drain metal M in a direction perpendicular to the gate width direction is less than or equal to a width H2 of the P-GaN layer 500, so that the drain metal M is in contact with only the P-GaN layer 500 but not with the AlGaN layer 400. In this way, the first structural interval 610 can implement local injection of holes.

FIG. 6 is a view of a partial section of a second structural interval 620 in a direction A according to Embodiment 1 of this disclosure. As shown in FIG. 6, in the second structural interval 620, the drain metal M is formed on the P-GaN layer 500 and on the AlGaN layer 400 that is on the two sides of the P-GaN layer 500. A width H3 of the drain metal M in a direction perpendicular to the gate width direction is greater than a width H2 of the P-GaN layer 500. In this case, on each side of the P-GaN layer 500, the drain metal M has a portion that is located outside a width range of the P-GaN layer 500, forming an extension portion 621. A portion of the gate metal located on the P-GaN layer 500 is in contact with the P-GaN layer 500, and the extension portions 621 of the drain metal M are directly formed on the AlGaN layer 400 and form ohmic contact (Ohmic contact) with the AlGaN layer 400. In this way, the second structural interval 620 can implement current conduction from the drain D to the source S of the device being in an operating state.

Further, it can be learned with reference to FIG. 6 that in the second structural interval 620, a section of the drain metal M may exhibit a concave structure, which snaps on the P-GaN layer 500. The drain metal M encloses the P-GaN layer 500 between the drain metal M and the AlGaN layer 400 by using the concave structure. Portions of the concave structure on two sides are the extension portions 621, and a middle portion of the concave structure is the portion formed on the P-GaN layer 500.

In this embodiment of this disclosure, that the first structural intervals 610 and the second structural intervals 620 are alternately distributed in the gate width direction means that in the gate width direction, one second structural interval 620 is disposed between any two adjacent first structural intervals 610, and one first structural interval 610 is disposed between any two adjacent second structural intervals 620, so that the plurality of first structural intervals 610 and the plurality of second structural intervals 620 can be evenly distributed in the gate width direction. In this way, the GaN device can evenly and alternately form hole injection areas and current conduction areas in the gate width direction, improving consistency in performance of the device at all positions in the gate width direction.

In this embodiment of this disclosure, a quantity of the first structural intervals 610 and a quantity of the second structural intervals 620 may be in a plurality of forms. For example, the quantity of the first structural intervals 610 and the quantity of the second structural intervals 620 may be related to a width of the gate. A larger width of the gate corresponds to a larger quantity of the first structural intervals 610 and a larger quantity of the second structural intervals 620. A smaller width of the gate corresponds to a smaller quantity of the first structural intervals 610 and a smaller quantity of the second structural intervals 620. In this way, regardless of the width of the gate, there is high consistency in performance of the device at all positions in the gate width direction by adjusting the quantity of the first structural intervals 610 and the quantity of the second structural intervals 620.

In this embodiment of this disclosure, a ratio of a length of the first structural interval 610 to a length of the second structural interval 620 in the gate width direction may be in a plurality of forms. A person skilled in the art may determine the ratio based on device performance actually required. For example, to obtain a GaN device with a high concentration of carriers, the length of the first structural interval 610 may be increased, and to improve a GaN device's capability of current conduction from a drain D to a source S, the length of the second structural interval 620 may be increased.

In this embodiment of this disclosure, shapes of the first structural interval 610 and the second structural interval 620 may be in a plurality of forms. For example, the first structural interval 610 and the second structural interval 620 may be rectangular, polygonal, circular, oval, or the like.

According to the foregoing structure, the drain metal M is in contact with only the P-GaN layer 500 in the first structural intervals 610, implementing local injection of holes, and the drain metal M forms ohmic contact (Ohmic contact) with the AlGaN layer 400 in the second structural intervals 620, implementing current conduction from the drain D to the source S of the device being in an operating state. Therefore, a risk of an increase in the intrinsic on-resistance of the device can be reduced while ensuring efficiency of hole injection at P-GaN. In addition, when the GaN device provided in Embodiment 1 of this disclosure is produced, the P-GaN layer 500 does not need to be etched into a discontinuous structure, thereby avoiding an impact of etching precision on performance of the device, and allowing a simpler process.

### Embodiment 2

Embodiment 2 of this disclosure provides a GaN device production method. The method is used to obtain the GaN device provided in Embodiment 1 of this disclosure or another GaN device.

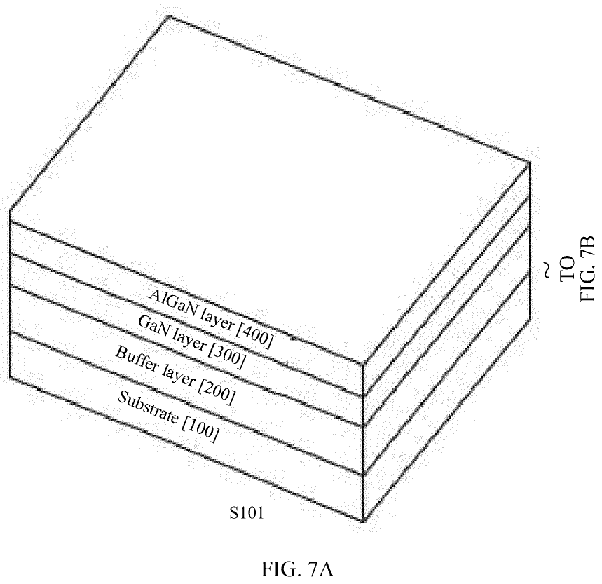

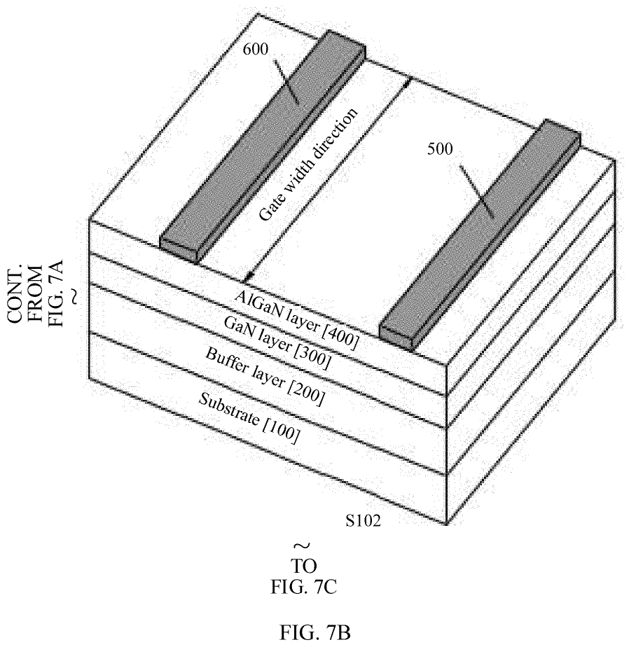

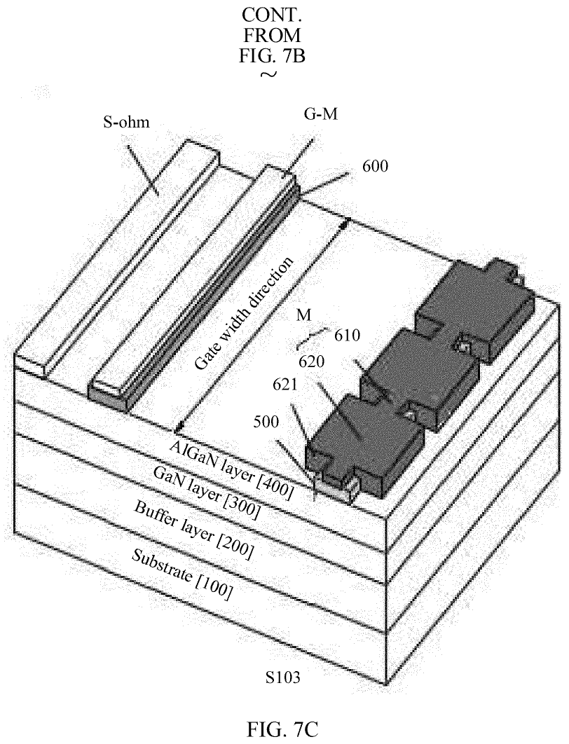

FIG. 7A, FIG. 7B, and FIG. 7C are a flowchart of a GaN device production method according to Embodiment 2 of this disclosure. As shown in FIG. 7A, FIG. 7B, and FIG. 7C, the method may include the following steps.

Step S101: Epitaxially grow a buffer layer 200, a GaN layer 300, and an AlGaN layer 400 sequentially from bottom to top on a substrate 100.

Step S101 is a conventional step of producing a GaN device and is not further elaborated in this embodiment of this disclosure.

Step S102: Etch a P-GaN layer 500 of a drain D on the AlGaN layer 400, where the P-GaN layer 500 is of a continuous strip structure in a gate width direction.

A step of etching a P-GaN layer 600 of a gate G on the AlGaN layer 400 may also be implemented in step S102. Etching the P-GaN layer 600 of the gate G on the AlGaN layer 400 is a conventional step of producing a GaN device and is not further elaborated in this embodiment of this disclosure.

Step S103: Produce a drain metal M on the P-GaN layer 500 and the AlGaN layer 400 that is located on two sides of the P-GaN layer 500.

The drain metal M may include a plurality of first structural intervals 610 and a plurality of second structural intervals 620 in the gate width direction. The first structural intervals 610 and the second structural intervals 620 are continuously and alternately distributed in the gate width direction.

In the first structural intervals 610, the drain metal M is etched only on the P-GaN layer 500. A width of the drain metal M in a direction perpendicular to the gate width direction is less than or equal to a width of the P-GaN layer 500, so that the drain metal M is in contact with only the P-GaN layer 500 but not with the AlGaN layer 400.

In the second structural intervals 620, on each side of the P-GaN layer 500, the drain metal M has a portion that is located outside a width range of the P-GaN layer 500, forming an extension portion 621. The extension portions 621 of the drain metal M are directly formed on the AlGaN layer 400 and form ohmic contact (Ohmic contact) with the AlGaN layer 400.

In addition, a step of growing a source metal S-ohm on the AlGaN layer 400 and a step of growing a gate metal G-M on the P-GaN layer 600 of the gate G may also be implemented in step S103. Growing the source metal S-ohm on the AlGaN layer 400 and growing the gate metal G-M on the P-GaN layer 600 of the gate G are both conventional steps of producing a GaN device and are not further elaborated in this embodiment of this disclosure.

It can be learned with reference to FIG. 7A, FIG. 7B, and FIG. 7C that when the GaN device provided in Embodiment 1 of this disclosure is produced, it is only necessary to generate the continuous strip P-GaN layer 500 by etching on the AlGaN layer 400, and it is not necessary to precisely etch the P-GaN layer 500 into P-GaN islands, thereby allowing a simple process and helping improve a good ratio and production efficiency of the devices.

### Embodiment 3

Embodiment 3 of this disclosure provides a GaN device, to reduce a risk of an increase in an intrinsic on-resistance of the device while ensuring efficiency of hole injection at P-GaN.

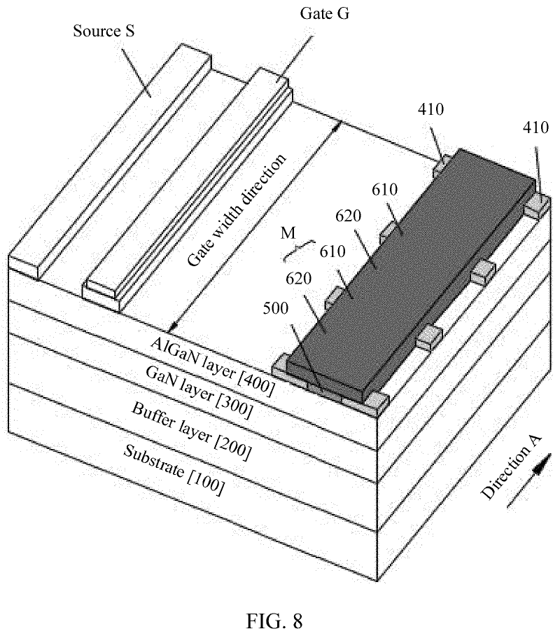

FIG. 8 is a three-dimensional view of a GaN device according to Embodiment 3 of this disclosure. As shown in FIG. 8, the GaN device includes a substrate (substrate) 100, a buffer layer 200 formed over the substrate 100, a GaN GaN layer 300 formed over the buffer layer 200, an aluminum GaN AlGaN layer 400 formed over the GaN GaN layer 300, and a source (S), a drain (D), and a gate (G) formed on the AlGaN layer 400. The drain (D) includes a P-GaN layer 500 formed on the AlGaN layer 400, and a drain metal M disposed on the P-GaN layer 500 and on the AlGaN layer 400 that is on two sides of the P-GaN layer 500.

In specific implementation, the P-GaN layer 500 is of a strip structure. The P-GaN layer 500 has a same width in all positions in a gate width direction. The drain metal M may include a plurality of first structural intervals 610 and a plurality of second structural intervals 620 in the gate width direction. The first structural intervals 610 and the second structural intervals 620 are alternately distributed in the gate width direction.

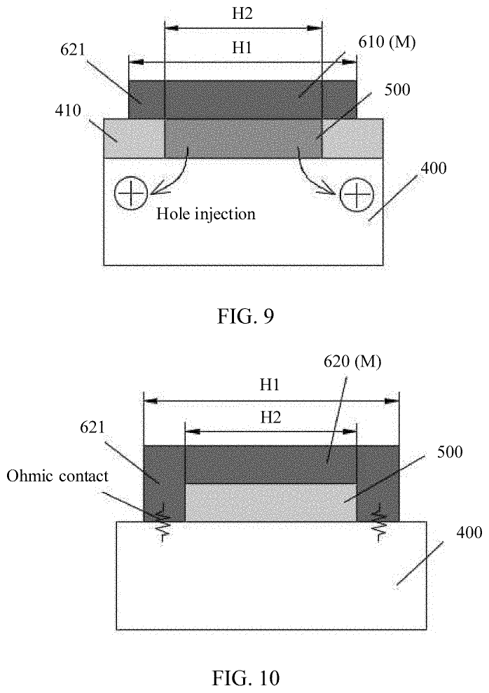

FIG. 9 is a view of a partial section of a first structural interval 610 according to Embodiment 3 of this disclosure. As shown in FIG. 9, in the first structural interval 610, the drain metal M is formed on the P-GaN layer 500 and on the AlGaN layer 400 that is on the two sides of the P-GaN layer 500. A width H1 of the drain metal M in a direction perpendicular to the gate width direction is greater than a width H2 of the P-GaN layer 500. In this case, on each side of the P-GaN layer 500, the drain metal M has a portion that is located outside a width range of the P-GaN layer 500, forming an extension portion 621. A portion of the drain metal M located on the P-GaN layer 500 is in contact with the P-GaN layer 500. In areas on a surface of the AlGaN layer 400 and under the extension portions 621, passivation layers 410 are retained. The extension portions 621 of the drain metal M are formed on the passivation layers 410, and are in contact with only the passivation layers 410 but not with the AlGaN layer 400, isolating the drain metal M from the AlGaN layer 400. In this way, the first structural interval 610 can implement local injection of holes. In addition, the P-GaN layer 500 in the first structural interval 610 may further function as a drain field plate. In this case, while implementing local injection of holes, the first structural interval 610 has a capability of balancing a high-voltage electric field at the drain, improving performance of the device.

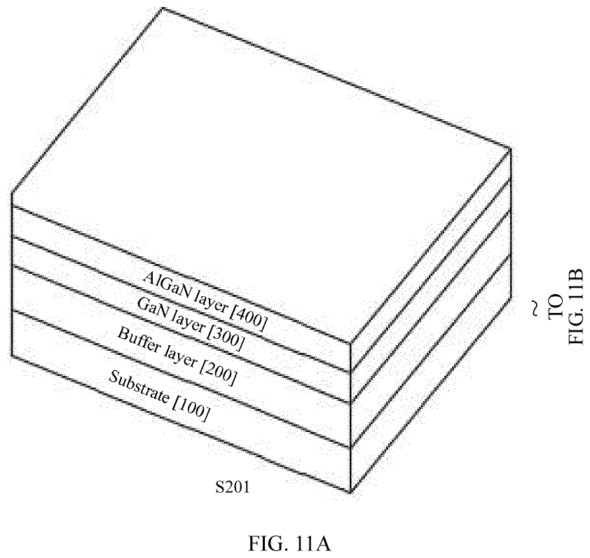

FIG. 10 is a view of a partial section of a second structural interval 620 according to Embodiment 3 of this disclosure. As shown in FIG. 10, in the second structural interval 620, similar to that in the first structural interval 610, the drain metal M is formed on the P-GaN layer 500 and on the AlGaN layer 400 that is on the two sides of the P-GaN layer 500. A width H1 of the drain metal M in the direction perpendicular to the gate width direction is greater than a width H2 of the P-GaN layer 500. In this case, on each side of the P-GaN layer 500, the drain metal M has a portion that is located outside a width range of the P-GaN layer 500, forming an extension portion 621. A portion of the drain metal M located on the P-GaN layer 500 is in contact with the P-GaN layer 500. In areas on a surface of the AlGaN layer 400 and under the extension portions 621, passivation layers 410 are not retained, that is, the passivation layers 410 are removed by etching. In this case, the extension portions 621 of the drain metal M are directly formed on the AlGaN layer 400 and form ohmic contact with the AlGaN layer 400. In this way, the second structural interval 620 can implement current conduction from the drain D to the source S of the device being in an operating state.

In a preferred implementation, the width of the drain metal M in the first structural interval 610 is the same as the width H1 of the drain metal M in the second structural interval 620, to reduce a difficulty of a process and facilitate production.

Further, it can be learned with reference to FIG. 9 and FIG. 10 that in both the first structural interval 610 and the second structural interval 620, a section of the drain metal M may exhibit a concave structure, which snaps on the P-GaN layer 500. The drain metal M encloses the P-GaN layer 500 by using the concave structure. Portions of the concave structure on two sides are the extension portions 621, and a middle portion of the concave structure is the portion that is in contact with the P-GaN layer 500.

According to the foregoing structure, the drain metal M is in contact with only the P-GaN layer 500 in the first structural intervals 610, implementing local injection of holes, and the drain metal M forms ohmic contact with the AlGaN layer 400 in the second structural intervals 620, implementing current conduction from the drain D to the source S of the device being in an operating state. Therefore, a risk of an increase in the intrinsic on-resistance of the device can be reduced while ensuring efficiency of hole injection at P-GaN. In addition, when the GaN device provided in Embodiment 3 of this disclosure is produced, the P-GaN layer 500 does not need to be etched into a discontinuous structure, thereby avoiding an impact of etching precision on performance of the device, and allowing a simpler process. In addition, the P-GaN layer 500 in the first structural interval 610 may further function as a drain field plate. In this case, while implementing local injection of holes, the first structural interval 610 has a capability of balancing a high-voltage electric field at the drain, improving performance of the device.

### Embodiment 4

Embodiment 4 of this disclosure provides a GaN device production method. The method is used to obtain the GaN device provided in Embodiment 3 of this disclosure or another GaN device.

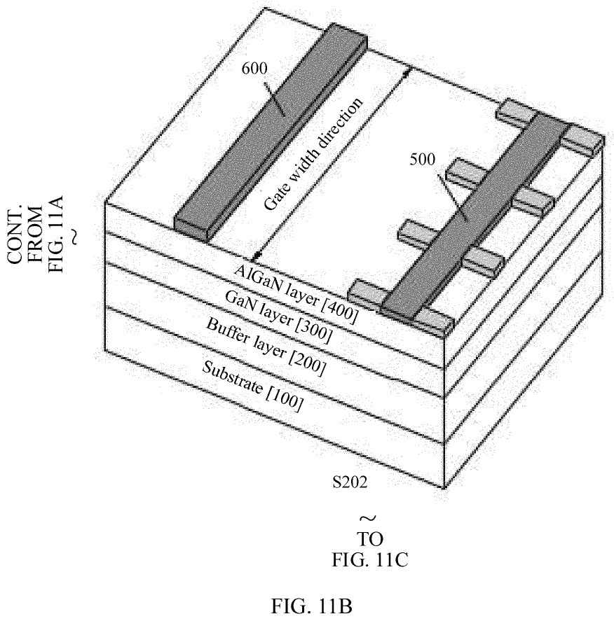

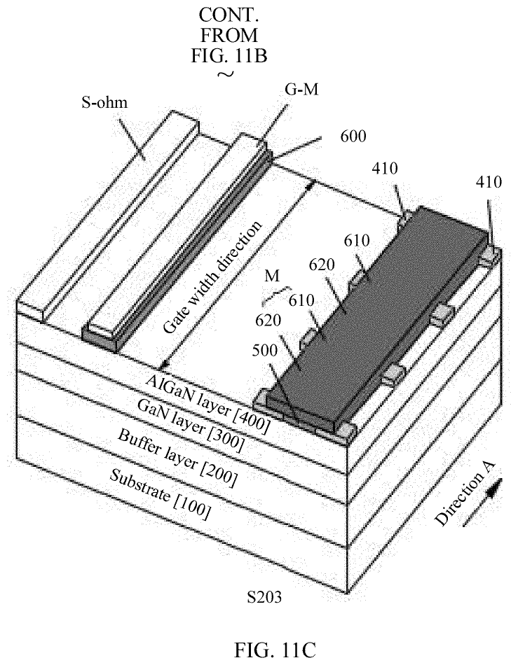

FIG. 11A, FIG. 11B, and FIG. 11C are a flowchart of a GaN device production method according to Embodiment 4 of this disclosure. As shown in FIG. 11A, FIG. 11B, and FIG. 11C, the method may include the following steps.

Step S201: Epitaxially grow a buffer layer 200, a GaN layer 300, and an AlGaN layer 400 sequentially from bottom to top on a substrate 100.

Step S201 is a conventional step of producing a GaN device and is not further elaborated in this embodiment of this disclosure.

Step S202: Etch a P-GaN layer 500 of a drain D on the AlGaN layer 400, where the P-GaN layer 500 of the drain D may be of a strip structure continuously generated in a gate width direction.

When the P-GaN layer 500 is etched, passivation layers 410 in areas on two sides of the P-GaN layer 500 may be retained at specific intervals in the gate width direction, that is, the passivation layers 410 may be removed by etching at intervals.

In addition, a step of etching a P-GaN layer 600 of a gate G on the AlGaN layer 400 may also be implemented in step S202. Etching the P-GaN layer 600 of the gate G on the AlGaN layer 400 is a conventional step of producing a GaN device and is not further elaborated in this embodiment of this disclosure.

Step S203: Produce a drain metal M on the P-GaN layer 500 and the AlGaN layer 400 that is located on the two sides of the P-GaN layer 500.

The drain metal M may be continuously distributed in the gate width direction.

A width of the drain metal M is greater than a width of the P-GaN layer 500. In this case, on each side of the P-GaN layer 500, the drain metal M has a portion that is located outside a width range of the P-GaN layer 500, forming an extension portion 621. Because the passivation layers 410 in the areas on the two sides of the P-GaN layer 500 are in different etching states, the drain metal M may include a plurality of first structural intervals 610 and a plurality of second structural intervals 620 in the gate width direction. The first structural intervals 610 and the second structural intervals 620 are continuously and alternately distributed in the gate width direction.

In areas in which the passivation layers 410 are retained (that is, areas in which the passivation layers 410 are not removed by etching), the drain metal M forms the first structural interval 610. In the first structural interval 610, a portion of the drain metal M located on the P-GaN layer 500 is in contact with the P-GaN layer 500, and the extension portions 621 of the drain metal M are formed on the passivation layers 410, and are in contact with only the passivation layers 410 but not with the AlGaN layer 400.

In areas in which the passivation layers 410 are etched (that is, areas in which the passivation layers 410 are removed), the drain metal M forms the second structural interval 620. In the second structural interval 620, a portion of the drain metal M located on the P-GaN layer 500 is in contact with the P-GaN layer 500, and the extension portions 621 of the drain metal M are directly formed on the AlGaN layer 400 and form ohmic contact with the AlGaN layer 400.

In addition, a step of growing a source metal S-ohm on the AlGaN layer 400 and a step of growing a gate metal G-M on the P-GaN layer 600 of the gate G may also be implemented in step S203. Growing the source metal S-ohm on the AlGaN layer 400 and growing the gate metal G-M on the P-GaN layer 600 of the gate G are both conventional steps of producing a GaN device and are not further elaborated in this embodiment of this disclosure.

It can be learned with reference to FIG. 11A, FIG. 11B, and FIG. 11C that when the GaN device provided in Embodiment 3 of this disclosure is produced, it is only necessary to generate the continuous strip P-GaN layer 500 by etching on the AlGaN layer 400, and it is not necessary to precisely etch the P-GaN layer 500 into P-GaN islands, thereby allowing a simple process and helping improve a good ratio and production efficiency of the devices.

### Embodiment 5

Embodiment 5 of this disclosure provides a GaN device.

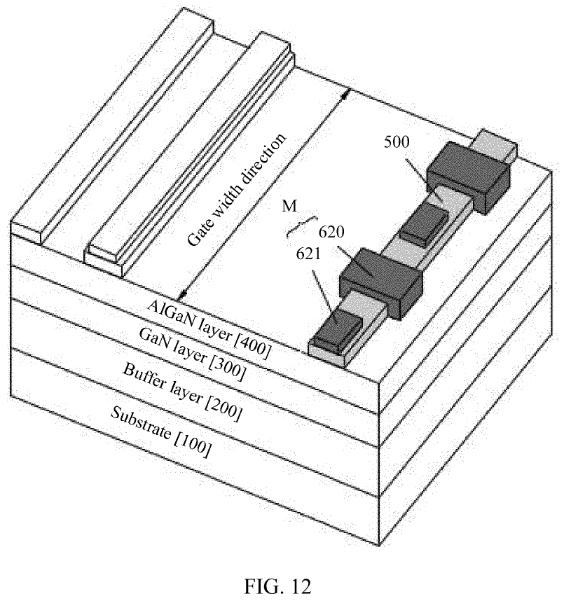

FIG. 12 is a three-dimensional view of a structure of the GaN device according to Embodiment 5 of this disclosure. In comparison with FIG. 4, it can be learned from FIG. 12 that a difference between the GaN device provided in Embodiment 5 of this disclosure and the GaN device provided in Embodiment 1 lies in that: first structural intervals 610 and second structural intervals 620 in a drain metal M are alternately distributed rather than continuously distributed in a gate width direction, and there is specific spacing between a first structural interval 610 and a second structural interval 620 that are adjacent. For remaining features that are not described in Embodiment 5 of this disclosure, refer to implementation of Embodiment 1 of this disclosure. Details are not described herein again.

An embodiment of this disclosure further provides an electronic device. The electronic device may be, for example, a power adapter, a rectifier, an inverter, a frequency converter, a server, a remote radio unit (RRU), or a switching power supply. The electronic device may include one or more GaN devices provided in embodiments of this disclosure.

An embodiment of this disclosure further provides a drive circuit including a gate driver and the GaN device according to the first aspect and the implementations of the first aspect in the embodiments of this disclosure. A gate of the GaN device is coupled to a signal output terminal of the gate driver, and a source and a drain of the GaN device are coupled into a load circuit. The gate driver is configured to output a first potential to turn on the GaN device, and output a second potential to turn off the GaN device, where the first potential is higher than a turn-on potential of the GaN device, and the second potential is lower than the turn-on potential of the GaN device.

Usually, the GaN device uses the gate for controlling, and electrical signals of different potentials are input to the gate, to control an on/off state of the GaN device. When the electrical signal input to the gate is higher than a critical potential, the GaN device is turned on. When the electrical signal input to the gate is lower than the potential, the GaN device is turned off. The critical potential may be referred to as the turn-on potential of the GaN device. In this embodiment of this disclosure, the first potential output by the gate driver may also be referred to as a high potential. Because the first potential is higher than the turn-on potential, the GaN device may be turned on. The second potential output by the gate driver may also be referred to as a low potential. Because the second potential is lower than the turn-on potential, the GaN device may be turned off, thereby implementing state control of the GaN device.

In this way, the GaN device may be used as a switching device in the load circuit, and is controlled to be on and off by the gate driver. Because the GaN device overcomes a “current collapse” effect and has a small intrinsic on-resistance and a small device loss, overall operating efficiency of the load circuit can be improved, a total amount of heat generated by the load circuit can be reduced, and operating stability of the load circuit can be improved.

It is easy to understand that a person skilled in the art may obtain other embodiments by combining, splitting, or reassembling embodiments of this disclosure based on the several embodiments provided in this disclosure, and these embodiments do not go beyond the protection scope of this disclosure.

The objectives, technical solutions, and benefits of the present disclosure are further described in detail in the foregoing specific embodiments. It should be understood that the foregoing description is merely specific embodiments of the present disclosure, but is not intended to limit the protection scope of the present disclosure. Any modification, equivalent replacement, or improvement made based on the technical solutions of the present disclosure shall fall within the protection scope of the present disclosure.

1. A gallium nitride (GaN) device, comprising:
a substrate;
a buffer layer disposed over the substrate;
a GaN layer disposed over the buffer layer;
an aluminum GaN (AlGaN) layer disposed over the GaN layer;
a source disposed on the AlGaN layer;
a gate disposed on the AlGaN layer; and
a drain disposed on the AlGaN layer and comprising:
a p-type GaN (P-GaN) layer disposed on the AlGaN layer, wherein the P-GaN layer is a strip structure in a gate width direction of the GaN device; and
a drain metal comprising:
a plurality of first structural intervals, wherein the drain metal is in contact with the P-GaN layer in the first structural intervals; and
a plurality of second structural intervals, wherein, in the second structural intervals, the drain metal is in contact with the P-GaN layer and configured to provide ohmic contact with the AlGaN layer, and
wherein the first structural intervals and the second structural intervals are alternately distributed in the gate width direction.

2. The GaN device of claim 1, wherein, in the first structural intervals, the drain metal is disposed on the P-GaN layer and a first width of the drain metal is less than or equal to a second width of the P-GaN layer.

3. The GaN device of claim 1, wherein, in the first structural intervals, the drain metal is disposed on the P GaN layer, a first width of the drain metal is greater than a second width of the P-GaN layer, and the drain metal comprises extension portions located on two sides of the P-GaN layer, and wherein the GaN device further comprises passivation layers configured to isolate the extension portions from the AlGaN layer.

4. The GaN device of claim 1, wherein, in the second structural intervals, the drain metal is disposed on the P-GaN layer and the AlGaN layer, a first width of the drain metal is greater than a second width of the P-GaN layer, and the drain metal comprises extension portions located on two sides of the P-GaN layer and configured to provide ohmic contact with the AlGaN layer.

5. The GaN device of claim 2, wherein, in the second structural intervals, the drain metal is disposed on the P-GaN layer and the AlGaN layer, the first width is greater than the second width, and the drain metal comprises extension portions located on two sides of the P-GaN layer and configured to provide ohmic contact with the AlGaN layer.

6. The GaN device of claim 3, wherein, in the second structural intervals, the drain metal is disposed on the P-GaN layer and the AlGaN layer, the first width is greater than the second width, and the drain metal comprises the extension portions, and wherein the extension portions are configured to provide ohmic contact with the AlGaN layer.

7. The GaN device of claim 1, wherein the P-GaN layer has a same width in all positions in the gate width direction.

8. The GaN device of claim 2, wherein the P-GaN layer has a same width in all positions in the gate width direction.

9. The GaN device of claim 3, wherein the P-GaN layer has a same width in all positions in the gate width direction.

10. The GaN device of claim 4, wherein the P-GaN layer has a same width in all positions in the gate width direction.

11. The GaN device of claim 4, wherein the drain metal has a same width in all positions in the gate width direction.

12. The GaN device of claim 1, wherein the first structural intervals and the plurality of second structural intervals are an integrated structure.

13. The GaN device of claim 1, wherein the first structural intervals and the second structural intervals are alternately distributed in the gate width direction, wherein the first structural intervals comprise a third structural interval, wherein the second structural intervals comprise a fourth structural interval that is adjacent to the third structural interval, and wherein the GaN device comprises a spacing between the first third structural interval and the second fourth structural interval.

14. A switching power transistor, comprising:
a gallium nitride (GaN) device comprising:
a substrate;
a buffer layer disposed over the substrate;
a GaN layer disposed over the buffer layer;
an aluminum GaN (AlGaN) layer disposed over the GaN layer;
a source disposed on the AlGaN layer;
a gate disposed on the AlGaN layer; and
a drain disposed on the AlGaN layer and comprising:
a p-type GaN (P-GaN) layer disposed on the AlGaN layer, wherein the P-GaN layer is a strip structure in a gate width direction of the GaN device; and
a drain metal comprising:
a plurality of first structural intervals, wherein the drain metal is in contact with the P-GaN layer in the first structural intervals; and
a plurality of second structural intervals, wherein, in the second structural intervals, the drain metal is in contact with the P-GaN layer and is configured to provide ohmic contact with the AlGaN layer, and
wherein the first structural intervals and the second structural intervals are alternately distributed in the gate width direction.

15. A drive circuit, comprising:
a gallium nitride (GaN) device comprising:
a substrate;
a buffer layer disposed over the substrate;
a GaN layer disposed over the buffer layer;
an aluminum GaN (AlGaN) layer disposed over the GaN layer;
a source disposed on the AlGaN layer and configured to couple to a load circuit;
a gate disposed on the AlGaN layer; and
a drain configured to couple to the load circuit and comprising:
a p-type GaN (P-GaN) layer disposed on the AlGaN layer, wherein the P-GaN layer is a strip structure in a gate width direction of the GaN device; and
a drain metal comprising:
a plurality of first structural intervals, wherein the drain metal is in contact with the P-GaN layer in the first structural intervals; and
a plurality of second structural intervals, wherein, in the second structural intervals, the drain metal is in contact with the P-GaN layer and configured to provide ohmic contact with the AlGaN layer, and
wherein the first structural intervals and the second structural intervals are alternately distributed in the gate width direction; and
a gate driver comprising a signal output terminal coupled to the gate, wherein the gate driver is configured to:
output a first potential to turn on the GaN device; and
output a second potential to turn off the GaN device,
wherein the first potential is higher than a turn-on potential of the GaN device, and
wherein the second potential is lower than the turn-on potential.

16. The drive circuit of claim 15, wherein, in the first structural intervals, the drain metal is disposed on the P-GaN layer and a first width of the drain metal is less than or equal to a second width of the P-GaN layer.

17. The drive circuit of claim 15, wherein, in the first structural intervals, the drain metal is disposed on the P-GaN layer, a first width of the drain metal is greater than a second width of the P-GaN layer, and the drain metal comprises extension portions located on two sides of the P-GaN layer, and wherein the GaN device further comprises passivation layers configured to isolate the extension portions from the AlGaN layer.

18. The drive circuit of claim 15, wherein, in the second structural intervals, the drain metal is disposed on the P-GaN layer and the AlGaN layer, a first width of the drain metal is greater than a second width of the P-GaN layer, and the drain metal comprises extension portions located on two sides of the P-GaN layer, and wherein the extension portions are configured to provide ohmic contact with the AlGaN layer.

19. The drive circuit of claim 15, wherein the P-GaN layer has a same width in all positions in the gate width direction.

20. The drive circuit of claim 18, wherein the drain metal has a same width in all positions in the gate width direction.
